(19) United States
(12) Patent Application Publication
(10) Pub. No.: US 2025/0101570 A1
(43) Pub. Date: Mar. 27, 2025

(54) DEPOSITION MASK AND METHOD FOR MANUFACTURING THE SAME

(71) Applicant: Samsung Display Co., LTD., Yongin-si, Gyeonggi-do (KR)

(72) Inventor: Hyun Eok SHIN, Yongin-si (KR)

(21) Appl. No.: 18/734,623

(22) Filed: Jun. 5, 2024

(30) Foreign Application Priority Data
Sep. 26, 2023 (KR) 10-2023-0128857

(51) Int. Cl. C23C 14/16; C23C 14/04; C23C 14/06; H10K 59/12

(52) U.S. Cl. CPC C23C 14/165; C23C 14/04; C23C 14/0641; H10K 59/12

(57) ABSTRACT

According to an embodiment, a method for manufacturing a deposition mask may include forming an inorganic film pattern on a silicon substrate, depositing a metal layer on the inorganic film pattern and openings of the inorganic film pattern, etching portions of the metal layer deposited on the openings of the inorganic film pattern, depositing a protective layer on the inorganic film pattern and the openings of the inorganic film pattern, removing the silicon substrate and the inorganic film pattern provided in each cell region, and removing the protective layer.

### CROSS-REFERENCE TO RELATED APPLICATION

The present application claims priority to and the benefit of f Korean Patent Application No. 10-2023-0128857, filed on Sep. 26, 2023, in the Korean Intellectual Property Office, the entire content of which is hereby incorporated by reference.

### BACKGROUND

### 1. Field

Embodiments of the present disclosure relate to a deposition mask and a method for manufacturing the same.

### 2. Description of the Related Art

Wearable devices that have the form of glasses or a helmet and form a focus at a distance close to a user's eyes in front of the user's eyes have been developed. For example, the wearable device may be a head mounted display (HMD) device or augmented reality (AR) glasses. Such a wearable device provides an augmented reality (hereinafter, referred to as “AR”) screen or a virtual reality (hereinafter referred to as “VR”) screen to a user.

The wearable device such as the HMD device or the AR glasses utilize a display specification of at least 2000 PPI (pixels per inch) in order for the user to use the wearable device for a long time without dizziness. To this end, an organic light emitting diode on silicon (OLEDoS) technology, which is a small organic light emitting display device having a high resolution, has emerged. The organic light emitting diode on silicon (OLEDoS) technology is a technology that provides organic light emitting diodes (OLEDs) on a semiconductor wafer substrate on which a complementary metal oxide semiconductor (CMOS) is provided.

To implement a high resolution of 2000 PPI or higher, a high resolution deposition mask is utilized. To this end, a silicon mask capable of being formed with precision of a semiconductor process has been researched and developed. The silicon mask is a mask that allows an inorganic film pattern deposited and formed on a silicon substrate to serve as a mask membrane. However, such a silicon mask may have a problem that damage occurs when the mask is cleaned due to a small thickness of the mask membrane.

### SUMMARY

Aspects of embodiments of the present disclosure provide a deposition mask capable of increasing rigidity of a mask membrane and easily adjusting a thickness of the mask by forming the mask membrane using a metal, and method for manufacturing the same.

According to an embodiment of the present disclosure, a method for manufacturing a deposition mask may include forming an inorganic film pattern on a silicon substrate, depositing a metal layer on the inorganic film pattern and openings of the inorganic film pattern, etching portions of the metal layer deposited on the openings of the inorganic film pattern, depositing a protective layer on the inorganic film pattern and the openings of the inorganic film pattern, removing the silicon substrate and the inorganic film pattern provided in each cell region, and removing the protective layer.

The silicon substrate may include a plurality of cell regions and a mask frame region excluding the plurality of cell regions, and the mask frame region may include a mask lip region partitioning the plurality of cell regions and an outer frame region provided at an outermost portion of the silicon substrate.

The forming of the inorganic film pattern may include forming the inorganic film pattern in each cell region of the silicon substrate.

The depositing of the metal layer may include depositing a first metal layer including a first metal, and depositing a second metal layer including a second metal, on the first metal layer.

The first metal may include at least one selected from vanadium (V), tantalum (Ta), and niobium (Nb).

The second metal may include titanium nitride (TIN).

The depositing of the metal layer may include a sputtering process.

The removing of the silicon substrate and the inorganic film pattern provided in each cell region may include forming a mask membrane in which only the metal layer remains by removing the inorganic film pattern from a structure in which the metal layer is stacked on the inorganic film pattern.

A cross section of the mask membrane may have a reverse tapered shape whose width increases from a bottom surface toward an upward direction.

The cross section of the mask membrane may have a bowl shape in which a space where the inorganic film pattern is removed is surrounded by the metal layer and is opened in the upward direction, and the upward direction is a direction from the deposition mask toward a substrate to be deposited.

The inorganic film pattern may include at least one selected from silicon (Si), silicon nitride (SiNx), silicon oxynitride (SiON), silicon oxide (SiOx), titanium oxide (TiOx), amorphous silicon (a-Si), and aluminum oxide (AlOx).

The etching of the portions of the metal layer deposited on the openings of the inorganic film pattern may include dry-etching the portions of the metal layer.

The protective layer may be an organic film including at least one selected from an acrylic resin, an epoxy resin, a phenolic resin, a polyamide resin, and a polyimide resin.

The removing of the silicon substrate and the inorganic film pattern provided in each cell region may include wet-etching a portion of the silicon substrate.

According to an embodiment of the present disclosure, a deposition mask may include a silicon substrate including a plurality of cell regions and a mask frame region excluding the plurality of cell regions, the mask frame region including a mask lip region partitioning the plurality of cell regions and an outer frame region provided at an outermost portion of the silicon substrate, and a mask membrane provided in each cell region and including a metal layer. A cross section of the mask membrane may have a bowl shape in which a space opened in an upward direction is surrounded by the metal layer in a lateral direction and a downward direction.

The cross section of the mask membrane may have a bowl shape in which the space is opened in the upward direction, and the upward direction is a direction from the deposition mask toward a substrate to be deposited.

The cross section of the mask membrane may have a reverse tapered shape whose width increases from a bottom surface toward the upward direction.

The metal layer may include a first metal layer including a first metal, and a second metal layer covering the first metal layer in the downward direction and including a second metal.

The first metal may include at least one selected from vanadium (V), tantalum (Ta), and niobium (Nb).

The second metal may include titanium nitride (TiN).

According to a method for manufacturing a deposition mask, by forming a mask membrane using a metal, it is possible to increase rigidity of the mask membrane and easily adjust a thickness of the mask.

In some embodiments, by allowing the mask membrane to have a reverse tapered shape, it is possible to reduce a shadow defect.

### BRIEF DESCRIPTION OF THE DRAWINGS

The above and other aspects and features of embodiments of the present disclosure will become more apparent by describing example embodiments in more detail exemplary embodiments with reference to the attached drawings, in which:

FIG. 1 is a perspective view illustrating a head mounted display device according to an example embodiment;

FIG. 2 is an exploded perspective view illustrating an example of the head mounted display device of FIG. 1;

FIG. 3 is a perspective view illustrating a head mounted display device according to an example embodiment;

FIG. 4 is an exploded perspective view illustrating a display device according to an example embodiment;

FIG. 5 is a cross-sectional view illustrating an example in which a portion of a display panel according to an example embodiment is cut;

FIG. 6 is a perspective view of a mask according to an example embodiment;

FIG. 7 is a schematic plan view of the mask according to an exemplary embodiment;

FIG. 8 is a flowchart illustrating a method for manufacturing a mask according to an exemplary embodiment;

FIGS. 9 to 14 are cross-sectional views illustrating processes of a method for manufacturing a mask according to an example embodiment;

FIG. 15 is a schematic cross-sectional view of the mask according to an example embodiment; and

FIG. 16 is a view illustrating a concept of a shadow region of the mask according to an example embodiment.

### DETAILED DESCRIPTION

Embodiments of the present disclosure will now be described more fully hereinafter with reference to the accompanying drawings, in which example embodiments of the disclosure are shown. The subject matter of this disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the spirit or scope of the present disclosure. Similarly, the second element could also be termed the first element.

Features of each of various embodiments of the present disclosure may be partially or entirely combined with each other and may technically variously interwork or interconnect with each other, and respective embodiments may be implemented independently of each other or may be implemented together in association with each other.

Hereinafter, example embodiments will be described with reference to the accompanying drawings.

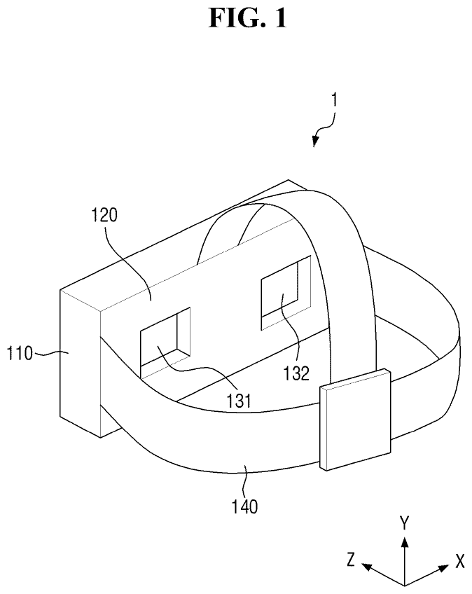

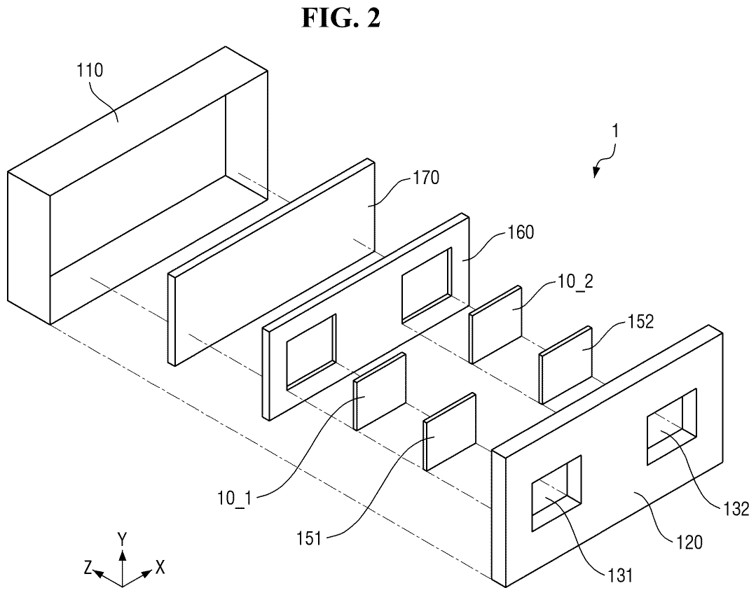

FIG. 1 is a perspective view illustrating a head mounted display device according to an example embodiment. FIG. 2 is an exploded perspective view illustrating an example of the head mounted display device of FIG. 1.

Referring to FIGS. 1 and 2, a head mounted display device 1 according to an example embodiment includes a first display device 10_1, a second display device 10_2, a display device housing part 110, a housing part cover 120, a first eyepiece 131, a second eyepiece 132, a head mounted band 140, a middle frame 160, a first optical member 151, a second optical member 152, a control circuit board 170, and a connector.

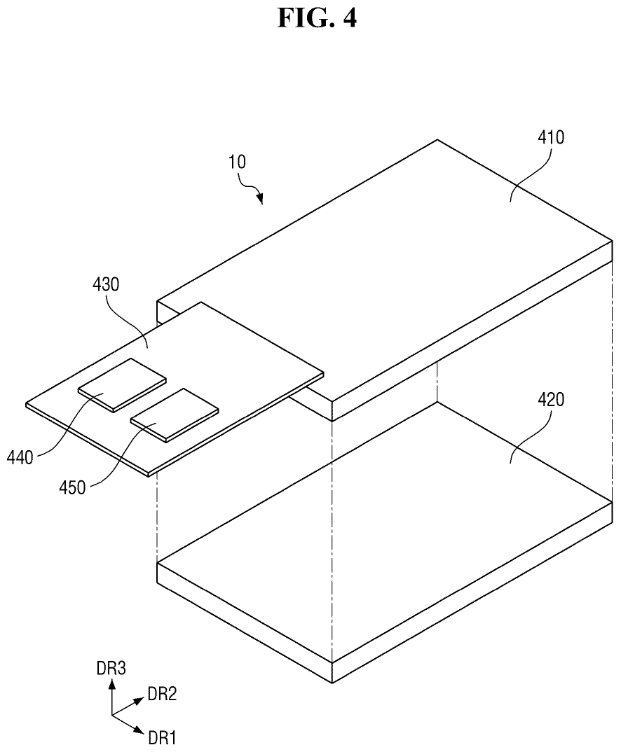

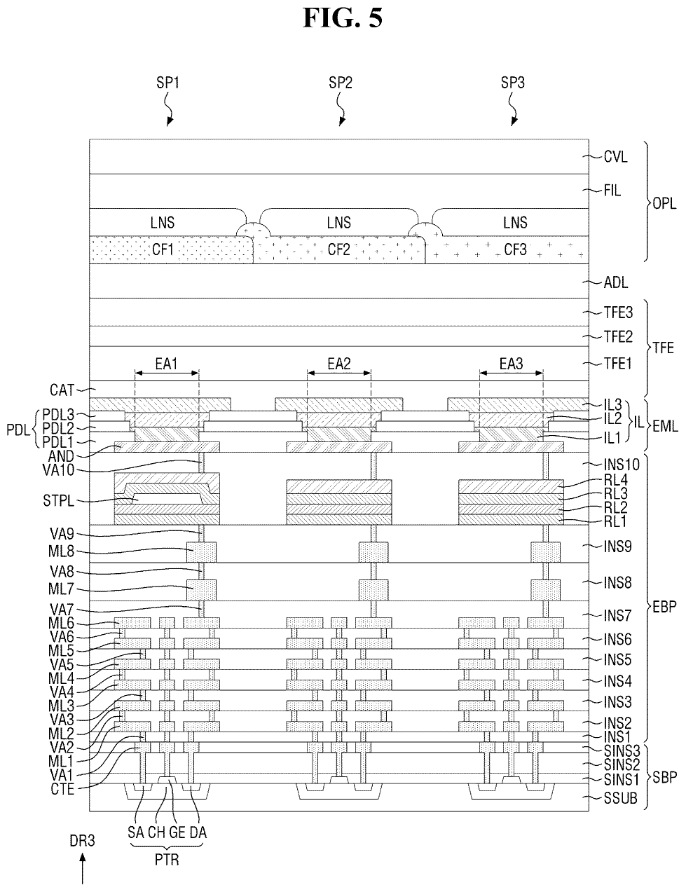

The first display device 10_1 provides an image to a user's left eye, and the second display device 10_2 provides an image to a user's right eye. Each of the first display device 10_1 and the second display device 10_2 is substantially the same as a display device 10 to be described with reference to FIGS. 4 and 5. Accordingly, a description of the first display device 10_1 and the second display device 10_2 will be replaced with a description to be provided with reference to FIGS. 4 and 5.

The first optical member 151 may be between the first display device 10_1 and the first eyepiece 131. The second optical member 152 may be between the second display device 10_2 and the second eyepiece 132. Each of the first optical member 151 and the second optical member 152 may include at least one convex lens.

The middle frame 160 may be between the first display device 10_1 and the control circuit board 170 and be between the second display device 10_2 and the control circuit board 170. The middle frame 160 serves to support and fix the first display device 10_1, the second display device 10_2, and the control circuit board 170.

The control circuit board 170 may be between the middle frame 160 and the display device housing part 110. The control circuit board 170 may be connected to the first display device 10_1 and the second display device 10_2 through the connector. The control circuit board 170 may convert an image source input from the outside into digital video data DATA, and transmit the digital video data DATA to the first display device 10_1 and the second display device 10_2 through the connector.

The control circuit board 170 may transmit digital video data DATA corresponding to a left eye image optimized or suited for the user's left eye to the first display device 10_1 and transmit digital video data DATA corresponding to a right eye image optimized or suited for the user's right eye to the second display device 10_2. In some embodiments, the control circuit board 170 may transmit the same digital video data DATA to the first display device 10_1 and the second display device 10_2.

The display device housing part 110 serves to house the first display device 10_1, the second display device 10_2, the middle frame 160, the first optical member 151, the second optical member 152, the control circuit board 170, and the connector. The housing part cover 120 is provided to cover an opened surface (e.g., an exposed surface) of the display device housing part 110. The housing part cover 120 may include the first eyepiece 131 to which the user's left eye corresponds and the second eyepiece 132 to which the user's right eye corresponds. It has been illustrated in FIGS. 1 and 2 that the first eyepiece 131 and the second eyepiece 132 are separately provided, but embodiments of the present disclosure are not limited thereto. The first eyepiece 131 and the second eyepiece 132 may be merged as one eyepiece.

The first eyepiece 131 may be aligned with the first display device 10_1 and the first optical member 151, and the second eyepiece 132 may be aligned with the second display device 10_2 and the second optical member 152. Accordingly, a user may view an image of the first display device 10_1 magnified as a virtual image by the first optical member 151 through the first eyepiece 131 and view an image of the second display device 10_2 magnified as a virtual image by the second optical member 152 through the second eyepiece 132.

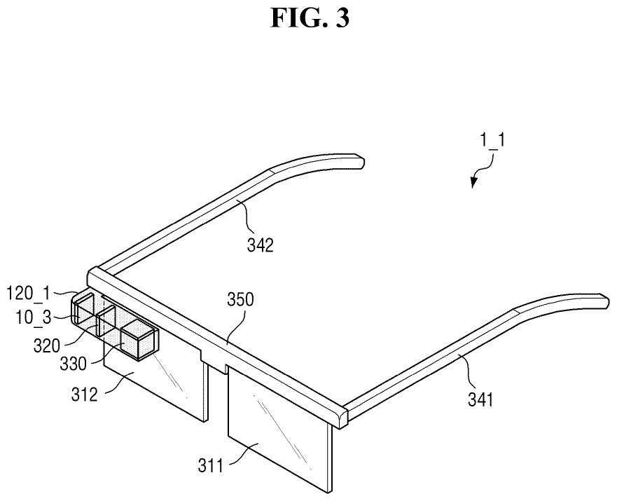

The head mounted band 140 serves to fix the display device housing part 110 to a user's head so that the first eyepiece 131 and the second eyepiece 132 of the housing part cover 120 may be maintained in a state in which they correspond to the user's left eye and right eye, respectively. When the display device housing part 120 is implemented to have a light weight and a small size, the head mounted display device 1 may include an eyeglass frame as illustrated in FIG. 3 instead of the head mounted band 140.

In some embodiments, the head mounted display device 1 may further include a battery that supplies power, an external memory slot for that houses an external memory (e.g., an external memory card or device), and an external connection port and a wireless communication module that receives an image source. The external connection port may include a universal serial bus (USB) terminal, a display port, and/or a high-definition multimedia interface (HDMI) terminal, and the wireless communication module may include a 5G communication module, a 4G communication module, a wireless fidelity (WiFi) module, and/or a Bluetooth module.

FIG. 3 is a perspective view illustrating a head mounted display device according to an example embodiment.

Referring to FIG. 3, a head mounted display device 1_1 according to an example embodiment may be a glasses-type display device in which a display device housing part 120_1 is implemented to have a light weight and a small size. The head mounted display device 1_1 according to an example embodiment may include a display device 10_3, a left eye lens 311, a right eye lens 312, a support frame 350, glasses frame legs 341 and 342, an optical member 320, an optical path conversion member 330, and the display device housing part 120_1.

The display device 10_3 illustrated in FIG. 3 is substantially the same as a display device 10 to be described with reference to FIGS. 4 and 5. Accordingly, a description of the display device 10_3 will be replaced with a description to be provided with reference to FIGS. 4 and 5.

The display device housing part 120_1 may include the display device 10_3, the optical member 320, and the optical path conversion member 330. An image displayed on the display device 10_3 may be magnified by the optical member 320, converted in an optical path by the optical path conversion member 330, and provided to a user's right eye through the right eye lens 312. For this reason, a user may view an augmented reality image in which a virtual image displayed on the display device 10_3 through his/her right eye and a real image seen through the right eye lens 312 are combined with each other.

It has been illustrated in FIG. 3 that the display device housing part 120_1 is provided at a right end of the support frame 350, but an example embodiment of the present disclosure is not limited thereto. For example, the display device housing part 120_1 may be provided at a left end of the support frame 350, and in this case, an image of the display device 10_3 may be provided to a user's left eye. In some embodiments, the display device housing parts 120_1 may be provided at both the left and right ends of the support frame 350, and in this case, the user may view an image displayed on the display device 10_3 through both his/her left and right eyes.

FIG. 4 is an exploded perspective view illustrating a display device according to an example embodiment.

Referring to FIG. 4, a display device 10 according to an example embodiment is a device that displays a moving image or a still image. The display device 10 according to an example embodiment may be applied to portable electronic devices such as mobile phones, smartphones, tablet personal computers (PCs), mobile communication terminals, electronic notebooks, electronic books, portable multimedia players (PMPs), navigation devices, and ultra mobile PCs (UMPCs). For example, the display device 10 may be applied as a display unit of televisions, laptop computers, monitors, billboards, and/or the Internet of Things (IOTs) devices. In some embodiments, the display device 10 may be applied to smart watches, watch phones, and/or head mounted displays (HMDs) for realizing virtual reality and/or augmented reality.

The display device 10 according to an exemplary embodiment includes a display panel 410, a heat dissipation layer 420, a circuit board 430, a driving circuit 440, and a power supply circuit 450.

The display panel 410 may have a shape similar to a rectangular shape in a plan view. For example, the display panel 410 may have a shape similar to a rectangular shape, in a plan view, having short sides in a first direction DR1 and long sides in a second direction DR2 crossing the first direction DR1. In the display panel 410, a corner where the short side in the first direction DR1 and the long side in the second direction DR2 meet may be rounded to have a set or predetermined curvature or may form a right-angle. The shape of the display panel 410 in a plan view is not limited to the rectangular shape, and may be a shape similar to other polygonal shapes, a circular shape, or an elliptical shape. A shape of the display device 10 in a plan view may follow the shape of the display panel 410 in a plan view, but embodiments of the present disclosure are not limited thereto.

The display panel 410 includes a display area that displays an image and a non-display area that does not display an image.

The display area includes a plurality of pixels, each of which includes a plurality of sub-pixels SP1, SP2, and SP3 (see FIG. 5). The plurality of sub-pixels SP1, SP2, and SP3 include a plurality of pixel transistors. The plurality of pixel transistors may be formed by a semiconductor process, and may be formed on a semiconductor substrate SSUB (see FIG. 5). For example, the plurality of pixel transistors may be formed as complementary metal oxide semiconductors (CMOSs).

The heat dissipation layer 420 may overlap the display panel 410 in a third direction DR3, which is a thickness direction of the display panel 410. The heat dissipation layer 420 may be on one surface, for example, a rear surface, of the display panel 410. The heat dissipation layer 420 serves to dissipate heat generated from the display panel 410. The heat dissipation layer 420 may include a metal layer such as graphite, silver (Ag), copper (Cu), and/or aluminum (Al) having high thermal conductivity.

The circuit board 430 may be electrically connected to a plurality of pads of a pad area of the display panel 410 using a conductive adhesive member (e.g., an electrically conductive adhesive member) such as an anisotropic conductive film. The circuit board 430 may be a flexible printed circuit board or a flexible film having a flexible material. It has been illustrated in FIG. 4 that the circuit board 430 is unbent, but the circuit board 430 may be bent. In some embodiments, one end of the circuit board 430 may be on the rear surface of the display panel 410. One end of the circuit board 430 may be an end opposite to the other end of the circuit board 430 connected to the plurality of pads of the pad area of the display panel 410 using the conductive adhesive member.

The driving circuit 440 may receive digital video data and timing signals from the outside. The driving circuit 440 may generate a scan timing control signal, an emission timing control signal, and a data timing control signal for controlling the display panel 410 according to the timing signals.

The power supply unit 450 may generate a plurality of panel driving voltages according to an external source voltage.

Each of the driving circuit 440 and the power supply unit 450 may be formed as an integrated circuit (IC) and attached to one surface of the circuit board 430.

FIG. 5 is a cross-sectional view illustrating an example in which a portion of a display panel according to an example embodiment is cut. For example, FIG. 5 illustrates a partial cross-sectional structure of the display area including the plurality of sub-pixels SP1, SP2, and SP3 (see FIG. 5).

Referring to FIG. 5, the display panel 410 includes a semiconductor backplane SBP, a light emitting element backplane EBP, a light emitting element layer EML, an encapsulation layer TFE, an optical layer OPL including a cover layer CVL, and a polarizing plate.

The semiconductor backplane SBP may include a semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively.

The semiconductor substrate SSUB may be a silicon substrate, a germanium substrate, or a silicon-germanium substrate. The semiconductor substrate SSUB may be a substrate doped with first-type impurities. A plurality of well regions may be provided in an upper surface of the semiconductor substrate SSUB. The plurality of well regions may be regions doped with second-type impurities. The second-type impurities may be different from the first-type impurities described above. For example, when the first-type impurities are p-type impurities, the second-type impurities may be n-type impurities. In some embodiments, when the first-type impurities are n-type impurities, the second-type impurities may be p-type impurities.

Each of the plurality of well regions includes a source region SA corresponding to a source electrode of the pixel transistor PTR, a drain region DA corresponding to a drain electrode of the pixel transistor PTR, and a channel region CH between the source region SA and the drain region DA.

Each of the source region SA and the drain region DA may be a region doped with the first-type impurities. A gate electrode GE of the pixel transistor PTR may overlap the well region WA in the third direction DR3. The channel region CH may overlap the gate electrode GE in the third direction DR3. The source region SA may be on one side of the gate electrode GE, and the drain region SA may be on the other side of the gate electrode GE.

Each of the plurality of well regions further includes a first low-concentration impurity region between the channel region CH and the source region SA and a second low-concentration impurity region between the channel region CH and the drain region DA. The first low-concentration impurity region may be a region having a lower impurity concentration than the source region SA. The second low-concentration impurity region may be a region having a lower impurity concentration than the drain region DA. A distance between the source region SA and the drain region DA may be increased by the first low-concentration impurity region and the second low-concentration impurity region. Therefore, a length of the channel region CH of each of the pixel transistors PTR may increase, and thus, punch-through and hot carrier phenomena caused by a short channel may be prevented (or an occurrence or likelihood thereof may be reduced).

A first semiconductor insulating film SINS1 may be on the semiconductor substrate SSUB. The first semiconductor insulating film SINS1 may be formed as a silicon nitride (SiCN) and/or silicon oxide (SiOₓ)-based inorganic film, but embodiments of the present disclosure are not limited thereto.

A second semiconductor insulating film SINS2 may be on the first semiconductor insulating film SINS1. The second semiconductor insulating film SINS2 may be formed as a silicon oxide (SiOₓ)-based inorganic film, but embodiments of the present disclosure are not limited thereto.

The plurality of contact terminals CTE may be on the second semiconductor insulating film SINS2. Each of the plurality of contact terminals CTE may be connected to any one selected from the gate electrode GE, the source region SA, and the drain region DA of each of the pixel transistors PTR through a hole penetrating through the first semiconductor insulating film SINS1 and the second semiconductor insulating film SINS2. Each of the plurality of contact terminals CTE may be made of any one selected from copper (Cu), aluminum (Al), tungsten (W), molybdenum (Mo), chromium (Cr), gold (Au), titanium (Ti), nickel (Ni), and neodymium (Nd), and/or alloys thereof.

A third semiconductor insulating film SINS3 may be on side surfaces of each of the plurality of contact terminals CTE. An upper surface of each of the plurality of contact terminals CTE may be exposed without being covered by the third semiconductor insulating film SINS3. The third semiconductor insulating film SINS3 may be formed as a silicon oxide (SiOₓ)-based inorganic film, but embodiments of the present disclosure are not limited thereto.

The semiconductor substrate SSUB may be replaced with a glass substrate and/or a polymer resin substrate such as a polyimide substrate. In some embodiments, thin film transistors may be on the glass substrate and/or the polymer resin substrate. The glass substrate may be a rigid substrate that is not bent, and the polymer resin substrate may be a flexible substrate that may be bent and/or curved.

The light emitting element backplane EBP includes first to eighth metal layers ML1 to ML8, reflective electrodes RL1 to RL4, a plurality of vias VA1 to VA10, and a step layer STPL. In some embodiments, the light emitting element backplane EBP includes a plurality of interlayer insulating films INS1 to INS10 respectively between the first to eighth metal layers ML1 to ML8.

The first to eighth metal layers ML1 to ML8 serve to implement a circuit of the first sub-pixel SP1 by connecting the plurality of contact terminals CTE exposed from the semiconductor backplane SBP to each other.

A first interlayer insulating film INS1 may be on the semiconductor backplane SBP. Each of first vias VA1 may penetrate through the first interlayer insulating film INS1 to be connected to the contact terminal CTE exposed from the semiconductor backplane SBP. Each of the first metal layers ML1 may be on the first interlayer insulating film INS1 and be connected to the first via VA1.

A second interlayer insulating film INS2 may be on the first interlayer insulating film INS1 and the first metal layers ML1. Each of second vias VA2 may penetrate through the second interlayer insulating film INS2 to be connected to the exposed first metal layer ML1. Each of the second metal layers ML2 may be on the second interlayer insulating film INS2 and be connected to the second via VA2.

A third interlayer insulating film INS3 may be on the second interlayer insulating film INS2 and the second metal layers ML2. Each of third vias VA3 may penetrate through the third interlayer insulating film INS3 to be connected to the exposed second metal layer ML2. Each of the third metal layers ML3 may be on the third interlayer insulating film INS3 and be connected to the third via VA3.

A fourth interlayer insulating film INS4 may be on the third interlayer insulating film INS3 and the third metal layers ML3. Each of fourth vias VA4 may penetrate through the fourth interlayer insulating film INS4 to be connected to the exposed third metal layer ML3. Each of the fourth metal layers ML4 may be on the fourth interlayer insulating film INS4 and be connected to the fourth via VA4.

A fifth interlayer insulating film INS5 may be on the fourth interlayer insulating film INS4 and the fourth metal layers ML4. Each of fifth vias VA5 may penetrate through the fifth interlayer insulating film INS5 to be connected to the exposed fourth metal layer ML4. Each of the fifth metal layers ML5 may be on the fifth interlayer insulating film INS5 and be connected to the fifth via VA5.

A sixth interlayer insulating film INS6 may be on the fifth interlayer insulating film INS5 and the fifth metal layers ML5. Each of sixth vias VA6 may penetrate through the sixth interlayer insulating film INS6 to be connected to the exposed fifth metal layer ML5. Each of the sixth metal layers ML6 may be on the sixth interlayer insulating film INS6 and be connected to the sixth via VA6.

A seventh interlayer insulating film INS7 may be on the sixth interlayer insulating film INS6 and the sixth metal layers ML6. Each of seventh vias VA7 may penetrate through the seventh interlayer insulating film INS7 to be connected to the exposed sixth metal layer ML6. Each of the seventh metal layers ML7 may be on the seventh interlayer insulating film INS7 and be connected to the seventh via VA7.

An eighth interlayer insulating film INS8 may be on the seventh interlayer insulating film INS7 and the seventh metal layers ML7. Each of eighth vias VA8 may penetrate through the eighth interlayer insulating film INS8 to be connected to the exposed seventh metal layer ML7. Each of the eighth metal layers ML8 may be on the eighth interlayer insulating film INS8 and be connected to the eighth via VA8.

The first to eighth metal layers ML1 to ML8 and the first to eighth vias VA1 to VA8 may be made of substantially the same material. Each of the first to eighth metal layers ML1 to ML8 and the first to eighth vias VA1 to VA8 may be made of any one selected from copper (Cu), aluminum (AI), tungsten (W), molybdenum (Mo), chromium (Cr), gold (Au), titanium (Ti), nickel (Ni), and neodymium (Nd), and/or alloys thereof. The first to eighth vias VA1 to VA8 may be made of substantially the same material. The first to eighth interlayer insulating films INS1 to INS8 may be formed as silicon oxide (SiOₓ)-based inorganic films, but embodiments of the present disclosure are not limited thereto.

Each of a thickness of the first metal layer ML1, a thickness of the second metal layer ML2, a thickness of the third metal layer ML3, a thickness of the fourth metal layer ML4, a thickness of the fifth metal layer ML5, and a thickness of the sixth metal layer ML6 may be greater than each of a thickness of the first via VA1, a thickness of the second via VA2, a thickness of the third via VA3, a thickness of the fourth via VA4, a thickness of the fifth via VA5, and a thickness of the sixth via VA6. Each of the thickness of the second metal layer ML2, the thickness of the third metal layer ML3, the thickness of the fourth metal layer ML4, the thickness of the fifth metal layer ML5, and the thickness of the sixth metal layer ML6 may be greater than the thickness of the first metal layer ML1. The thickness of the second metal layer ML2, the thickness of the third metal layer ML3, the thickness of the fourth metal layer ML4, the thickness of the fifth metal layer ML5, and the thickness of the sixth metal layer ML6 may be substantially the same as each other.

Each of a thickness of the seventh metal layer ML7 and a thickness of the eighth metal layer ML8 may be greater than each of the thickness of the first metal layer ML1, the thickness of the second metal layer ML2, the thickness of the third metal layer ML3, the thickness of the fourth metal layer ML4, the thickness of the fifth metal layer ML5, and the thickness of the sixth metal layer ML6. Each of the thickness of the seventh metal layer ML7 and the eighth metal layer ML8 may be greater than each of a thickness of the seventh via VA7 and a thickness of the eighth via VA8. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh metal layer ML7 and the thickness of the eighth metal layer ML8 may be substantially the same as each other.

A ninth interlayer insulating film INS9 may be on the eighth interlayer insulating film INS8 and the eighth metal layer ML8. The ninth interlayer insulating film INS9 may be formed as a silicon oxide (SiOₓ)-based inorganic film, but embodiments of the present disclosure are not limited thereto.

Each of ninth vias VA9 may penetrate through the ninth interlayer insulating film INS9 to be connected to the exposed eighth metal layer ML8. Each of the ninth vias VA9 may be made of any one selected from copper (Cu), aluminum (Al), tungsten (W), molybdenum (Mo), chromium (Cr), gold (Au), titanium (Ti), nickel (Ni), and neodymium (Nd), and/or alloys thereof.

Each of first reflective electrodes RL1 may be on the ninth interlayer insulating film INS9 and be connected to the ninth via VA9. Each of the first reflective electrodes RL1 may be made of any one selected from copper (Cu), aluminum (Al), tungsten (W), molybdenum (Mo), chromium (Cr), gold (Au), titanium (Ti), nickel (Ni), and neodymium (Nd), and/or alloys thereof.

Each of second reflective electrodes RL2 may be on the first reflective electrode RL1. Each of the second reflective electrodes RL2 may be made of any one selected from copper (Cu), aluminum (Al), tungsten (W), molybdenum (Mo), chromium (Cr), gold (Au), titanium (Ti), nickel (Ni), and neodymium (Nd), and/or alloys thereof. For example, each of the second reflective electrodes RL2 may be made of titanium nitride (TiN).

In the first sub-pixel SP1, the step layer STPL may be on the second reflective electrode RL2. The step layer STPL may not be provided in each of the second sub-pixel SP2 and the third sub-pixel SP3. The step layer STPL may be formed as a silicon nitride (SiCN) and/or silicon oxide (SiOₓ)-based inorganic film, but embodiments of the present disclosure are not limited thereto.

In the first sub-pixel SP1, a third reflective electrode RL3 may be on the second reflective electrode RL2 and the step layer STPL. In the second sub-pixel SP2 and the third sub-pixel SP3, third reflective electrodes RL3 may be on the second reflective electrodes RL2. Each of the third reflective electrodes RL3 may be made of any one selected from copper (Cu), aluminum (Al), tungsten (W), molybdenum (Mo), chromium (Cr), gold (Au), titanium (Ti), nickel (Ni), and neodymium (Nd), and/or alloys thereof.

At least one of the first reflective electrodes RL1, the second reflective electrodes RL2, and the third reflective electrodes RL3 may be omitted.

Each of fourth reflective electrodes RL4 may be on the third reflective electrode RL3. The fourth reflective electrodes RL4 may be layers reflecting light from first to third intermediate layers IL1, IL2, and IL3. The fourth reflective electrodes RL4 may include a metal having high reflectivity so as to be advantageous or beneficial in reflecting the light. Each of the fourth reflective electrodes RL4 may be made of aluminum (Al), a stacked structure (Ti/Al/Ti) of aluminum and titanium, a stacked structure (ITO/Al/ITO) of aluminum and indium tin oxide (ITO), silver (Ag), palladium (Pd), an APC alloy, which is an alloy of copper (Cu), and/or a stacked structure (ITO/APC/ITO) of an APC alloy and/or ITO, but embodiments of the present disclosure are not limited thereto.

A tenth interlayer insulating film INS10 may be on the ninth interlayer insulating film INS9 and the fourth reflective electrodes RL4. The tenth interlayer insulating film INS10 may be formed as a silicon oxide (SiOₓ)-based inorganic film, but embodiments of the present disclosure are not limited thereto.

Each of tenth vias VA10 may penetrate through the tenth interlayer insulating film VA10 to be connected to the exposed fourth reflective electrode RL4. Each of the tenth vias VA10 may be made of any one selected from copper (Cu), aluminum (Al), tungsten (W), molybdenum (Mo), chromium (Cr), gold (Au), titanium (Ti), nickel (Ni), and neodymium (Nd), and/or alloys thereof. Due to the step layer STPL, a thickness of the tenth via VA10 in the first sub-pixel SP1 may be smaller than a thickness of the tenth via VA10 in each of the second sub-pixel SP2 and the third sub-pixel SP3.

The light emitting element layer EML may be on the light emitting element backplane EBP. The light emitting element layer EML may include light emitting elements each including a first electrode AND, an intermediate layer IL (e.g., including first to third intermediate layers IL1, IL2, and IL3), and a second electrode CAT, and a pixel defining film PDL.

The first electrode AND of each of the light emitting elements may be on the tenth interlayer insulating film INS10 and be connected to the tenth via VA10. The first electrode AND of each of the light emitting elements may be connected to the drain region DA or the source region SA of the pixel transistor PTR through the tenth via VA10, the first to fourth reflective electrodes RL1 to RL4, the first to ninth vias VA1 to VA9, the first to eighth metal layers ML1 to ML8, and the contact terminal CTE. The first electrode AND of each of the light emitting elements may be made of any one of copper (Cu), aluminum (Al), tungsten (W), molybdenum (Mo), chromium (Cr), gold (Au), titanium (Ti), nickel (Ni), and neodymium (Nd), or alloys thereof. For example, the first electrode AND of each of the light emitting elements may be made of titanium nitride (TiN).

The pixel defining film PDL may be on a partial area of the first electrode AND of each of the light emitting elements. The pixel defining film PDL may cover an edge of the first electrode AND of each of the light emitting elements. The pixel defining film PDL serves to partition first emission areas EA1, second emission areas EA2, and third emission areas EA3.

The first emission area EA1 may be defined as an area in which the first electrode AND, the intermediate layer IL, and the second electrode CAT are sequentially stacked in the first sub-pixel SP1 to emit light. The second emission area EA2 may be defined as an area in which the first electrode AND, the intermediate layer IL, and the second electrode CAT are sequentially stacked in the second sub-pixel SP2 to emit light. The third emission area EA3 may be defined as an area in which the first electrode AND, the intermediate layer IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be on the edge of the first electrode AND of each of the light emitting elements, the second pixel defining film PDL2 may be on the first pixel defining film PDL1, and the third pixel defining film PDL3 may be on the second pixel defining film PDL2. The first pixel defining film PDL1, the second pixel defining film PDL2, and the third pixel defining film PDL3 may be formed as silicon oxide (SiOₓ)-based inorganic films, but embodiments of the present disclosure are not limited thereto.

The intermediate layer IL may include a first intermediate layer IL1, a second intermediate layer IL2, and a third intermediate layer IL3.

The intermediate layer IL may have a tandem structure including a plurality of intermediate layers IL1, IL2, and IL3 that emit different light. For example, the intermediate layer IL may include a first intermediate layer IL1 that emits light of a first color, a second intermediate layer IL2 that emits light of a third color, and a third intermediate layer IL3 that emits light of a second color. The first intermediate layer IL1, the second intermediate layer IL2, and the third intermediate layer IL3 may be sequentially stacked.

The first intermediate layer IL1 may have a structure in which a first hole transporting layer, a first organic light emitting layer that emits the light of the first color, and a first electron transporting layer are sequentially stacked. The second intermediate layer IL2 may have a structure in which a second hole transporting layer, a second organic light emitting layer that emits the light of the third color, and a second electron transporting layer are sequentially stacked. The third intermediate layer IL3 may have a structure in which a third hole transporting layer, a third organic light emitting layer that emits the light of the second color, and a third electron transporting layer are sequentially stacked.

The intermediate layer IL may cover the first electrodes AND at openings of the pixel defining film PDL and cover the pixel defining film PDL between the sub-pixels SP1, SP2, and SP3 provided to neighbor to each other, and may be partially disconnected.

In an example embodiment, by disconnecting the intermediate layer IL between adjacent sub-pixels SP1, SP2, and SP3, it is possible to prevent or reduce a leakage current between adjacent sub-pixels SP1, SP2, and SP3 and prevent a color interference phenomenon (or reduce a likelihood or occurrence thereof). The color interference phenomenon refers to, for example, a phenomenon in which a red sub-pixel adjacent to a blue sub-pixel is unintentionally turned on while the blue sub-pixel emits light of a blue color. The color interference phenomenon occurs due to the leakage current, and may occur when the blue sub-pixel and the red sub-pixel that have a great difference in voltage driving the pixels are adjacent to each other. For example, the leakage current is a phenomenon in which a portion of a driving current is transferred to the red sub-pixel through at least some conductive layers (e.g., electrically conductive layers) of the intermediate layer IL while the driving current is supplied to a light emitting element LE of the blue sub-pixel in order to turn on the blue sub-pixel. When the leakage current occurs, the red sub-pixel may be unintentionally turned on while the blue sub-pixel is turned on.

The number of intermediate layers IL1, IL2, and IL3 that emit the different light is not limited to that illustrated in FIG. 5. For example, the intermediate layer IL may include two intermediate layers. In some embodiments, any one of the two intermediate layers may be substantially the same as the first intermediate layer IL1, and the other of the two intermediate layers may include a second hole transporting layer, a second organic light emitting layer, a third organic light emitting layer, and a second electron transporting layer. In some embodiments, a charge generation layer that supplies electrons to any one intermediate layer and supplies charges to the other intermediate layer may be between the two intermediate layers.

It has been illustrated in FIG. 5 that the first to third intermediate layers IL1, IL2, and IL3 are all provided in the first emission area EA1, the second emission area EA2, and the third emission area EA3, but embodiments of the present disclosure are not limited thereto. For example, the first intermediate layer IL1 may be provided in the first emission area EA1, and may not be provided in the second emission area EA2 and the third emission area EA3. In some embodiments, the second intermediate layer IL2 may be provided in the second emission area EA2, and may not be provided in the first emission area EA1 and the third emission area EA3. In some embodiments, the third intermediate layer IL3 may be provided in the third emission area EA3, and may not be provided in the first emission area EA1 and the second emission area EA2. In some embodiments, first to third color filters CF1, CF2, and CF3 of the optical layer OPL may be omitted.

The second electrode CAT may be on the third intermediate layer IL3. The second electrode CAT may be on the third intermediate layer IL3 in each of a plurality of trenches formed between sub-pixels. The second electrode CAT may be made of a transparent conductive material (TCO) such as ITO and/or indium zinc oxide (IZO) capable of transmitting light therethrough or a semi-transmissive conductive material (e.g., a semi-transmissive electrically conductive material) such as magnesium (Mg), silver (Ag), or an alloy of magnesium (Mg) and silver (Ag). When the second electrode CAT is made of the semi-transmissive conductive material, emission efficiency of each of the first to third sub-pixels SP1, SP2, and SP3 may be increased by a micro cavity.

The encapsulation layer TFE may be on the light emitting element layer EML. The encapsulation layer TFE may include at least one inorganic film TFE1 and TFE3 in order to prevent or reduce permeation of oxygen and/or moisture into the light emitting element layer EML. In some embodiments, the encapsulation layer TFE may include at least one organic film in order to protect the light emitting element layer EML from foreign substances such as dust. For example, the encapsulation layer TFE may include a first encapsulation inorganic film TFE1, an encapsulation organic film TFE2, and a second encapsulation inorganic film TFE3.

The first encapsulation inorganic film TFE1 may be on the second electrode CAT, the encapsulation organic film TFE2 may be on the first encapsulation inorganic film TFE1, and the second encapsulation inorganic film TFE3 may be on the encapsulation organic film TFE2. The first encapsulation inorganic film TFE1 and the second encapsulation inorganic film TFE3 may be formed as multiple films in which one or more inorganic films selected from a silicon nitride (SiNₓ) layer, a silicon oxynitride (SiON) layer, a silicon oxide (SiOₓ) layer, a titanium oxide (TiOₓ) layer, and an aluminum oxide (AlOₓ) layer are alternately stacked. The encapsulation organic film TFE2 may be made of a monomer. In some embodiments, the encapsulation organic film TFE2 may be an organic film made of an acrylic resin, an epoxy resin, a phenolic resin, a polyamide resin, a polyimide resin, and/or the like.

An adhesive layer ADL may be a layer that adheres the encapsulation layer TFE and the optical layer OPL to each other. The adhesive layer ADL may be a double-sided adhesive member. In some embodiments, the adhesive layer ADL may be a transparent adhesive member such as a transparent adhesive and/or a transparent adhesive resin.

The optical layer OPL includes a plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may be on the adhesive layer ADL.

The first color filter CF1 may overlap the first emission area EA1 of the first sub-pixel SP1. The first color filter CF1 may transmit the light of the first color, for example, light of a blue wavelength band, therethrough. The blue wavelength band may be approximately 370 nm to 460 nm. Therefore, the first color filter CF1 may transmit the light of the first color among light emitted from the first emission area EA1 therethrough.

The second color filter CF2 may overlap the second emission area EA2 of the second sub-pixel SP2. The second color filter CF2 may transmit the light of the second color, for example, light of a green wavelength band, therethrough. The green wavelength band may be approximately 480 nm to 560 nm. Therefore, the second color filter CF2 may transmit the light of the second color among light emitted from the second emission area EA2 therethrough.

The third color filter CF3 may overlap the third emission area EA3 of the third sub-pixel SP3. The third color filter CF3 may transmit the light of the third color, for example, light of a red wavelength band, therethrough. The red wavelength band may be approximately 600 nm to 750 nm. Therefore, the third color filter CF3 may transmit the light of the third color among light emitted from the third emission area EA3 therethrough.

Each of the plurality of lenses LNS may be on each of the first color filter CF1, the second color filter CF2, and the third color filter CF3. Each of the plurality of lenses LNS may be a structure for increasing a ratio of light directed to a front surface of the display device 10. Each of the plurality of lenses LNS may have a cross-sectional shape convex in an upward direction.

The filling layer FIL may be on the plurality of lenses LNS. The filling layer FIL may have a set or predetermined refractive index so that light travels in the third direction DR3 at an interface between the plurality of lenses LNS and the filling layer FIL. In some embodiments, the filling layer FIL may be a planarizing layer. The filling layer FIL may be an organic film made of an acrylic resin, an epoxy resin, a phenolic resin, a polyamide resin, a polyimide resin, and/or the like.

A cover layer CVL may be on the filling layer FIL. The cover layer CVL may be a glass substrate and/or a polymer resin such as a resin. When the cover layer CVL is the glass substrate, the cover layer CVL may be attached onto the filling layer FIL. In some embodiments, the filling layer FIL may serve to adhere the cover layer CVL. When the cover layer CVL is the glass substrate, the cover layer CVL may serve as an encapsulation substrate. When the cover layer CVL is the polymer resin such as the resin, the cover layer CVL may be directly applied onto the filling layer FIL.

The polarizing plate may be on one surface of the cover layer CVL. The polarizing plate may be a structure that prevents or reduces deterioration in visibility due to external light reflection. The polarizing plate may include a linear polarizing plate and a phase retardation film. For example, the phase retardation film may be a λ/4 plate (quarter-wave plate), but embodiments of the present disclosure are not limited thereto. However, when visibility due to external light reflection is suitably or sufficiently improved by the first to third color filters CF1, CF2, and CF3, the polarizing plate may be omitted.

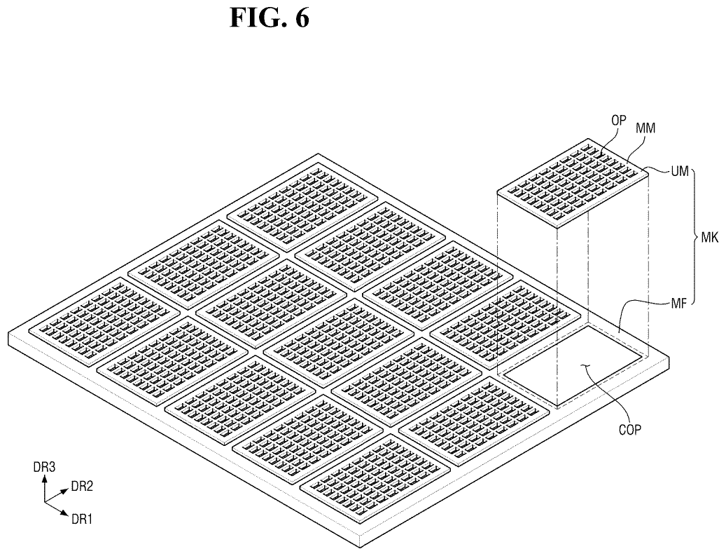

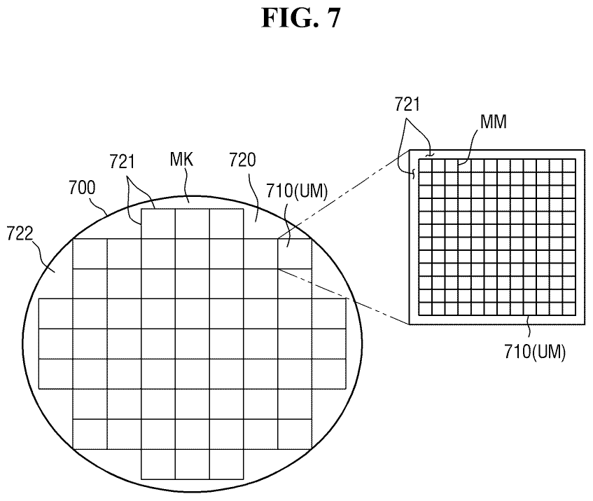

FIG. 6 is a perspective view of a mask according to an example embodiment. FIG. 7 is a schematic plan view of the mask according to an example embodiment.

FIG. 6 is a perspective view illustrating a state in which one unit mask UM of a plurality of unit masks is separated. The mask according to an example embodiment illustrated in FIGS. 6 and 7 may be used in a process of depositing at least a portion of the intermediate layer IL of the display panel 410 described with reference to FIG. 5. For example, the intermediate layer IL may be configured to emit different colors from each of the sub-pixels SP1, SP2, and SP3.

Referring to FIGS. 6 and 7, the mask MK according to an example embodiment may be a shadow mask in which mask membranes MM are on a silicon substrate 700. The mask MK according to an example embodiment may be referred to as a “silicon mask”.

According to an example embodiment, the mask MK may include the silicon substrate 700, and the mask membranes MM may be on the silicon substrate 700. The mask membranes MM may be provided in cell regions 710 arranged in a matrix form, and the respective cell regions 710 may be surrounded by a mask lip region 721. The mask lip region 721 may be a region in which a portion of the silicon substrate may be provided, and may serve to support the mask membranes MM.

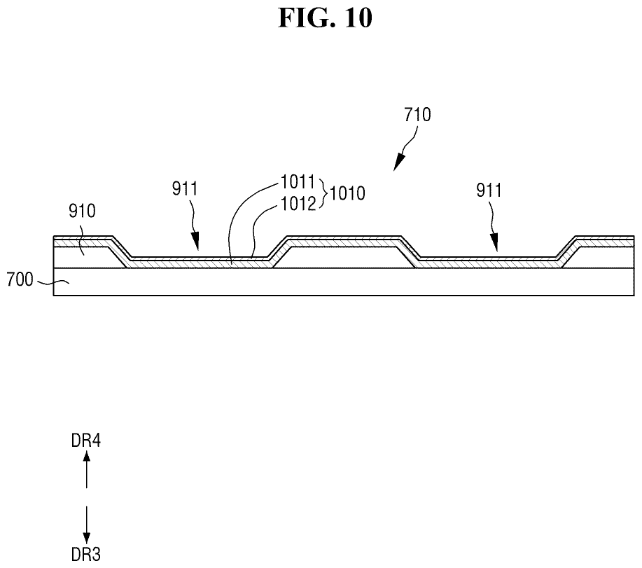

The mask membrane MM may be a portion of the unit mask UM provided in each of a plurality of cell regions 710. The mask membrane MM is formed by a metal layer 1010 (see FIG. 10). The mask membrane MM includes a metal material, and may thus be referred to as a “metal mask membrane MM”.

The silicon substrate 700 may include the plurality of cell regions 710 and a mask frame region 720 excluding the plurality of cell regions 710. The mask frame region 720 may include the mask lip region 721 surrounding the respective cell regions 710 and an outer frame region 722 provided at the outermost portion of the silicon substrate 700. A mask frame MF may be provided in the mask frame region 720, and may include mask lips surrounding the cell regions 710.

The mask lip region 721 may be a region partitioning the plurality of cell regions 710. For example, the plurality of cell regions 710 may be arranged in the matrix form, and the mask lip region 721 may be provided to surround the respective cell regions 710.

A cell opening COP and the unit mask UM masking at least a portion of the cell opening COP may be provided in each of the plurality of cell regions 710 of the silicon substrate 700.

A plurality of cell openings COP may penetrate through the mask frame MF along a thickness direction (e.g., the third direction DR3) of the mask MK. The plurality of cell openings COP may be formed by etching portions of the silicon substrate 700 from a rear surface direction.

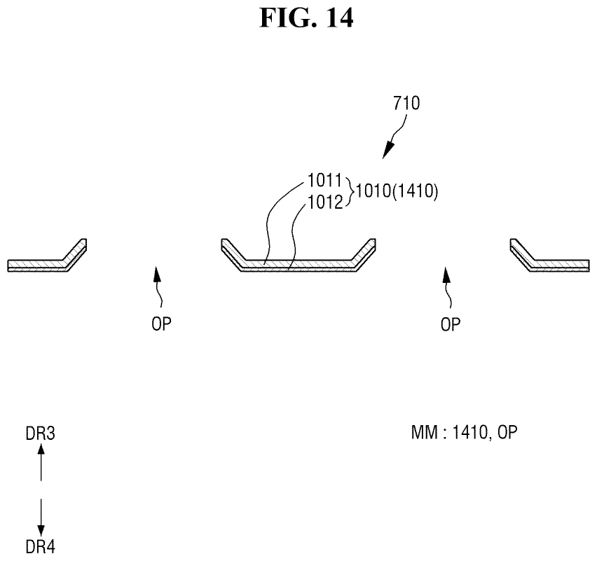

Each unit mask UM may include the mask membrane MM, and the mask membrane MM may include mask openings OP. Mask shadows 1410 (see FIG. 14) may be provided in a matrix form within each unit mask UM, and the mask openings OP may be between the mask shadows 1410. For example, the mask shadows 1410 may be provided to surround the respective mask openings OP.

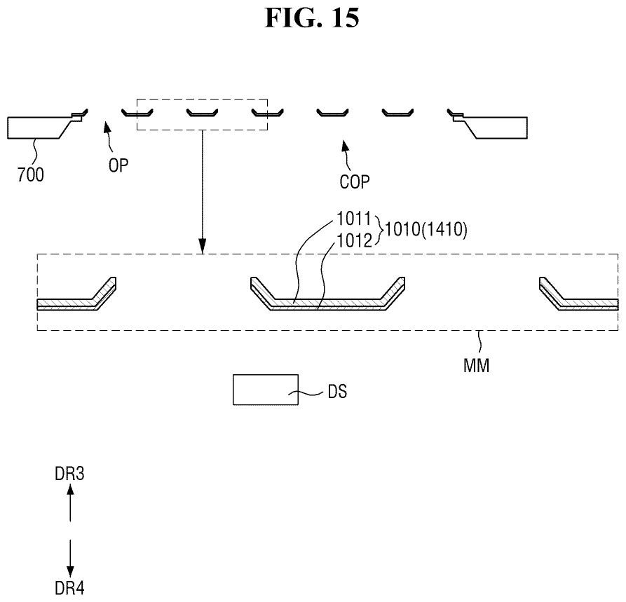

The mask shadow 1410 may serve as a blocking part masking a substrate to be deposited (e.g., the display panel 410 or a backplane substrate) when a deposition material evaporates from a deposition source DS (see FIG. 15) inside a deposition device. Accordingly, the deposition material generated from the deposition source DS may be deposited on a surface of the substrate to be deposited (e.g., the display panel 410 or the backplane substrate) through the mask openings OP of the mask membrane MM.

The mask opening OP of the mask membrane MM may be referred to as a “hole” or a “mask hole”. The mask openings OP may penetrate through the unit masks UM along the thickness direction (e.g., the third direction DR3) of the mask MK.

One unit mask UM may be used in a deposition process of one display panel 410. In embodiments of the present disclosure, the term “unit mask UM” may be replaced with the term such as a mask unit UM or a unit mask UM.

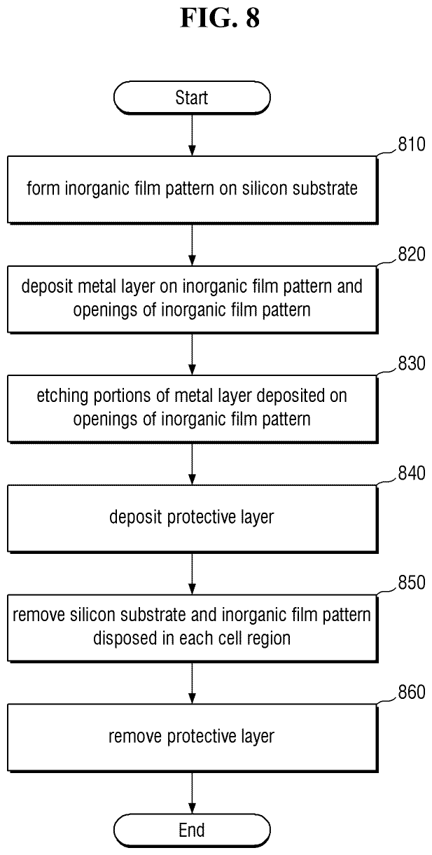

FIG. 8 is a flowchart illustrating a method for manufacturing a mask according to an exemplary embodiment.

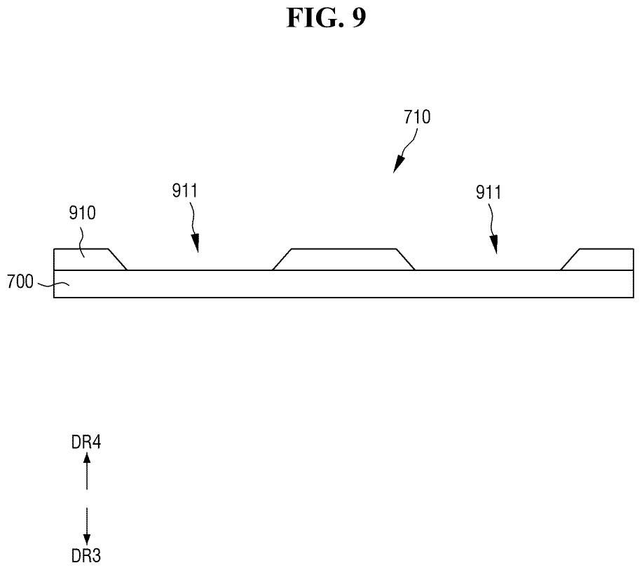

FIGS. 9 to 14 are cross-sectional views for describing processes of the method for manufacturing a mask according to an exemplary embodiment.

Hereinafter, a method for manufacturing a mask according to an example embodiment will be described with reference to FIGS. 8 to 14. The following description is only a description of some of processes for manufacturing a mask, and processes for forming the components described with reference to the present disclosure may be additionally performed before or after each step. In some embodiments, any suitable processes for manufacturing a mask generally used in the art may be additionally performed before or after each step to be described below.

Referring to FIGS. 8 and 9, in step 810, an inorganic film pattern 910 may be formed on the silicon substrate 700. The silicon substrate 700 includes the plurality of cell regions 710 and the mask frame region 720 excluding the plurality of cell regions 710. The mask frame region 720 includes the mask lip region 721 partitioning the plurality of cell regions 710 and the outer frame region 722 provided at the outermost portion of the silicon substrate 700. Step 810 may be a step of forming the inorganic film pattern 910 in each cell region 710 of the silicon substrate 700.

According to an example embodiment, the inorganic film patterns 910 may be provided at intervals on the silicon substrate 700 in each cell region 710. Accordingly, the inorganic film pattern 910 may include a plurality of openings 911 in each cell region 710.

According to an example embodiment, the inorganic film pattern 910 may have a regular tapered shape. This is to ensure that when a metal layer 1010 is deposited on the inorganic film pattern 910 in a subsequent process, the deposited metal layer 1010 becomes a mask membrane MM having a reverse tapered shape.

The inorganic film pattern 910 may be formed by depositing an inorganic film on the silicon substrate 700 and then patterning the deposited inorganic film.

The inorganic film pattern 910 may include at least one selected from silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ).

Referring to FIGS. 8 and 10, in step 820, the metal layer 1010 may be deposited on the inorganic film pattern 910 and the openings 911 of the inorganic film pattern 910. The metal layer 1010 may include multiple films including a first metal layer 1011 and a second metal layer 1012. For example, a step of depositing the metal layer 1010 may include a step of depositing the first metal layer 1011 including a first metal and a step of depositing the second metal layer 1012 including a second metal on the first metal layer 1011.

In the method for manufacturing a mask according to an example embodiment, the mask membrane MM is formed using the metal layer 1010 deposited through a sputtering process. In such an example embodiment, the mask membrane MM may be manufactured to have a smaller thickness than a mask membrane MM according to a comparative example formed using a plating film. For example, the mask membrane MM according to an example embodiment may have a thickness less than about 0.3 μm.

According to an example embodiment, the first metal included in the first metal layer 1011 includes at least one selected from vanadium (V), tantalum (Ta), and niobium (Nb). The second metal included in the second metal layer 1012 includes titanium-nitride (TiN). The first metal layer 1011 is made of at least one selected from vanadium (V), tantalum (Ta), and niobium (Nb), and accordingly, resistance to acid chemicals in a subsequent process of etching the silicon substrate 700 may be increased and dry etching may be easily performed. The second metal layer 1012 is made of titanium-nitride (TiN), and accordingly, may have a Young's Modulus of about 550 MPa to prevent or reduce warpage and have strong scratch resistance.

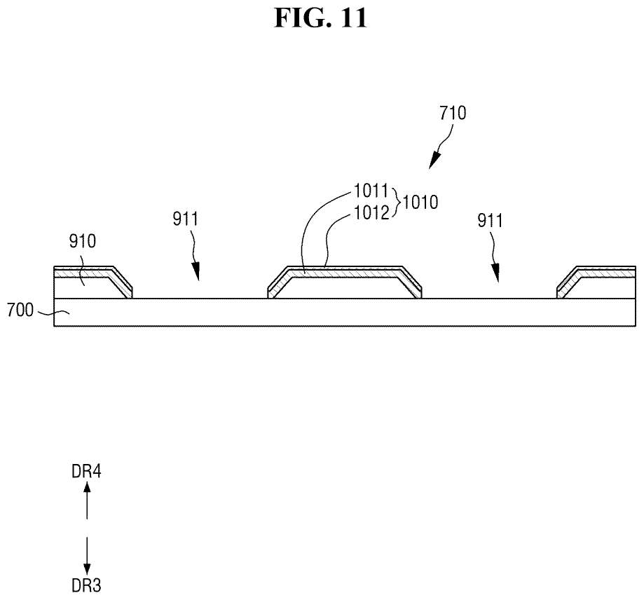

Referring to FIGS. 8 and 11, in step 830, portions of the metal layer 1010 deposited on the openings 911 of the inorganic film pattern 910 may be etched. For example, the metal layer 1010 may be removed in the openings 911 of the inorganic film pattern 910. A process of removing the metal layer 1010 includes a step of dry-etching portions of the metal layer 1010. After a process according to step 830 is performed, the metal layer 1010 remains only on a surface of the inorganic film pattern 910.

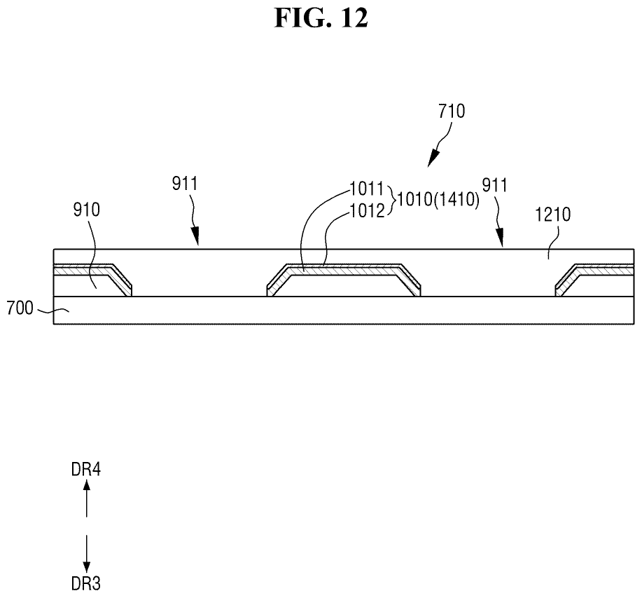

Referring to FIGS. 8 and 12, in step 840, a protective layer 1210 may be deposited. The protective layer 1210 may be an organic film including at least one selected from an acrylic resin, an epoxy resin, a phenolic resin, a polyamide resin, and a polyimide resin. The protective layer 1210 may cover the openings 911 of the inorganic film pattern 910 and the metal layer 1010 deposited on the inorganic film pattern 910. After the protective layer 1210 is deposited, the silicon substrate 700 may be overturned. For example, after the protective layer 1210 is deposited, the silicon substrate 700 may be overturned so that the protective layer 1210 is directed toward a downward direction DR4.

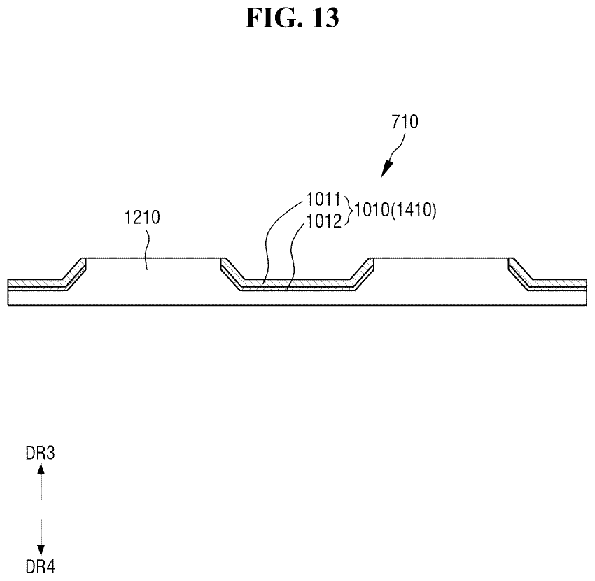

Referring to FIGS. 8 and 13, in step 850, the silicon substrate 700 and the inorganic film pattern 910 provided in each cell region 710 may be removed. After the silicon substrate 700 is overturned, the silicon substrate 700 and the inorganic film pattern 910 corresponding to each cell region 710 are removed. A step of removing the silicon substrate 700 provided in each cell region 710 includes a step of wet-etching a portion of the silicon substrate 700. The metal layer 1010 may have strong resistance during the wet-etching of the silicon substrate 700. This is because the first metal layer 1011 is made of at least one selected from vanadium (V), tantalum (Ta), and niobium (Nb), as described above.

Referring to FIGS. 8 and 14, in step 860, the protective layer 1210 may be removed. After the protective layer 1210 is removed, only the metal layer 1010 substantially remains in each cell region 710. The metal layer 1010 serves as the mask membrane MM in each cell region 710.

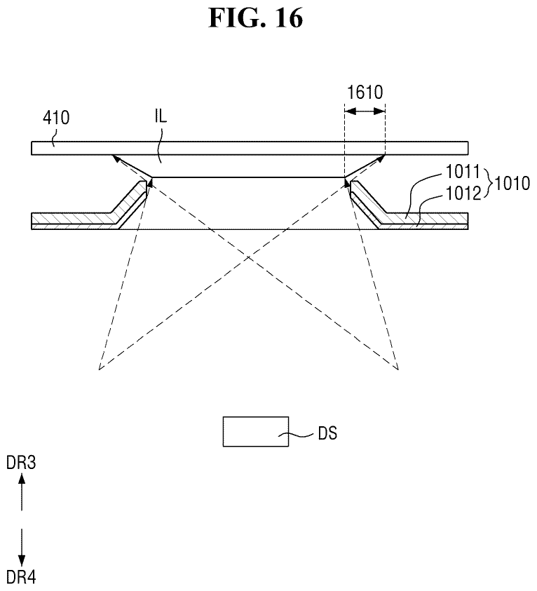

A cross section of the mask membrane MM (e.g., a cross section of the mask shadow) has a reverse tapered shape whose width increases from a bottom surface directed toward the downward direction DR4 toward an upward direction DR3. For example, the cross section of the mask membrane MM has a bowl shape in which a space where the inorganic film pattern 910 is removed is surrounded by the metal layer 1010 and is opened in the upward direction DR3. Here, the upward direction DR3 is a direction from a deposition mask toward a substrate to be deposited (e.g., 410 in FIG. 16).

FIG. 15 is a schematic cross-sectional view of the mask according to an example embodiment. For example, the mask according to an example embodiment may finally have a cross-sectional structure as illustrated in FIG. 15 through a manufacturing process described with reference to FIGS. 8 to 14.

Referring to FIG. 15, in the mask MK according to an example embodiment, the mask membrane MM provided in each cell region 710 and including the metal layer 1010 is provided. The cross section of the mask membrane MM (e.g., the cross section of the mask shadow 1410) has the bowl shape in which the space opened in the upward direction DR3 is surrounded by the metal layer 1010 in a lateral direction and the downward direction DR4. Here, the downward direction DR4 is a direction in which the deposition source DS is provided.

FIG. 16 is a view illustrating a concept of a shadow region of the mask according to an example embodiment. For example, FIG. 16 illustrates a state in which the mask described with reference to FIGS. 8 to 15 and the substrate to be deposited are aligned with each other. In FIG. 16, reference numeral 410 denotes the display panel 410, which is the substrate to be deposited.

Referring to FIG. 16, in the mask MK according to an example embodiment, the cross section of the mask membrane MM (e.g., the cross-section of the mask shadow 1410) has the reverse tapered shape, and accordingly, an area of a shadow region 1610 may be reduced. For example, a taper angle of the cross section of the mask shadow 1410 formed by the metal layer 1010 may be smaller than or equal to a deposition incident angle, which is a minimum angle from the deposition source DS to the mask opening OP, and accordingly, an area of the shadow region 1610 may be reduced.

With the method for manufacturing a deposition mask according to example embodiments, by forming the mask membrane MM using a metal, it is possible to increase rigidity of the mask membrane MM and easily adjust a thickness of the mask.

In some embodiments, by allowing the mask membrane MM to have the reverse tapered shape, it is possible to reduce a shadow defect.

In concluding the detailed description, those skilled in the art will appreciate that many variations and modifications can be made to the preferred embodiments without substantially departing from the principles of the present disclosure. Therefore, the disclosed embodiments of the present disclosure are used in a generic and descriptive sense only and not for purposes of limitation.

What is claimed is:

1. A method for manufacturing a deposition mask, the method comprising:
forming an inorganic film pattern on a silicon substrate;
depositing a metal layer on the inorganic film pattern and openings of the inorganic film pattern;
etching portions of the metal layer deposited on the openings of the inorganic film pattern;
depositing a protective layer on the inorganic film pattern and the openings of the inorganic film pattern;
removing the silicon substrate and the inorganic film pattern provided in each cell region; and
removing the protective layer.

2. The method of claim 1, wherein the silicon substrate comprises a plurality of cell regions and a mask frame region excluding the plurality of cell regions, and
the mask frame region comprises a mask lip region partitioning the plurality of cell regions and an outer frame region provided at an outermost portion of the silicon substrate.

3. The method of claim 2, wherein the forming of the inorganic film pattern comprises forming the inorganic film pattern in each cell region of the silicon substrate.

4. The method of claim 3, wherein the depositing of the metal layer comprises:
depositing a first metal layer comprising a first metal; and
depositing a second metal layer comprising a second metal, on the first metal layer.

5. The method of claim 4, wherein the first metal comprises at least one selected from vanadium (V), tantalum (Ta), and niobium (Nb).

6. The method of claim 5, wherein the second metal comprises titanium nitride (TiN).

7. The method of claim 4, wherein the depositing of the metal layer comprises a sputtering process.

8. The method of claim 1, wherein the removing of the silicon substrate and the inorganic film pattern provided in each cell region comprises forming a mask membrane in which only the metal layer remains by removing the inorganic film pattern from a structure in which the metal layer is stacked on the inorganic film pattern.

9. The method of claim 8, wherein a cross section of the mask membrane has a reverse tapered shape whose width increases from a bottom surface toward an upward direction.

10. The method of claim 9, wherein the cross section of the mask membrane has a bowl shape in which a space where the inorganic film pattern is removed is surrounded by the metal layer and is opened in the upward direction, and
the upward direction is a direction from the deposition mask toward a substrate to be deposited.

11. The method of claim 1, wherein the inorganic film pattern includes at least one selected from silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ).

12. The method of claim 1, wherein the etching of the portions of the metal layer deposited on the openings of the inorganic film pattern comprises dry-etching the portions of the metal layer.

13. The method of claim 1, wherein the protective layer comprises an organic film comprising at least one selected from an acrylic resin, an epoxy resin, a phenolic resin, a polyamide resin, and a polyimide resin.

14. The method of claim 1, wherein the removing of the silicon substrate and the inorganic film pattern provided in each cell region comprises wet-etching a portion of the silicon substrate.

15. A deposition mask comprising:
a silicon substrate comprising a plurality of cell regions and a mask frame region excluding the plurality of cell regions, the mask frame region comprising a mask lip region partitioning the plurality of cell regions and an outer frame region provided at an outermost portion of the silicon substrate; and
a mask membrane provided in each cell region and comprising a metal layer,
wherein a cross section of the mask membrane has a bowl shape in which a space opened in an upward direction is surrounded by the metal layer in a lateral direction and a downward direction.

16. The deposition mask of claim 15, wherein the cross section of the mask membrane has a bowl shape in which the space is opened in the upward direction, and
the upward direction is a direction from the deposition mask toward a substrate to be deposited.

17. The deposition mask of claim 16, wherein the cross section of the mask membrane has a reverse tapered shape whose width increases from a bottom surface toward the upward direction.

18. The deposition mask of claim 17, wherein the metal layer comprises:
a first metal layer comprising a first metal; and
a second metal layer covering the first metal layer in the downward direction and comprising a second metal.

19. The deposition mask of claim 18, wherein the first metal includes at least one selected from vanadium (V), tantalum (Ta), and niobium (Nb).

20. The deposition mask of claim 18, wherein the second metal comprises titanium nitride (TiN).
